(19) United States
(12) Patent Application Publication
(10) Pub. No.: US 2019/0280047 A1
(43) Pub. Date: Sep. 12, 2019

(54) DUAL PEDESTAL MEMORY

(71) Applicant: Intel Corporation, Santa Clara, CA (US)

(72) Inventors: Tejaswik K. Indukuri, Portland, OR (US); Ravi Pillarisetty, Portland, OR (US); Elijah V. Karpov, Portland, OR (US); Satyarth Suri, Portland, OR (US)

(73) Assignee: Intel Corporation, Santa Clara, CA (US)

(21) Appl. No.: 16/320,306

(22) PCT Filed: Sep. 30, 2016
(86) PCT No.: PCT/US2016/054601

§ 371 Date: Jan. 24, 2019

(51) Int. Cl. H01L 27/24; H01L 27/22; H01L 27/11507

(52) U.S. Cl. CPC H01L 27/2463; H01L 27/11507; H01L 27/222

(57) ABSTRACT

Substrates, assemblies, and techniques for enabling a dual pedestal for resistive random access memory are disclosed herein. For example, in some embodiments, a device may include a substrate, wherein the substrate includes a fill metal, a first pedestal on the substrate, wherein the first pedestal is over the fill metal, and a second pedestal over the first pedestal, where the second pedestal is a bottom electrode for a memory cell. In an example, the first pedestal extends at least a length of the fill metal and the second pedestal extends less than a length of the first pedestal. In addition, the device can include a memory cell over the second pedestal.

### CROSS-REFERENCE TO RELATED APPLICATION

This application is a national stage application under 35 U.S.C. § 371 of PCT International Application Serial No. PCT/US2016/054601, filed on Sep. 30, 2016 and entitled “Dual Pedestal Memory,” which is hereby incorporated by reference herein in its entirety.

### TECHNICAL FIELD

The present disclosure relates generally to the field of integrated circuits, and more particularly, to substrates, assemblies, and techniques to enable a dual pedestal for memory.

### BACKGROUND

Most, if not all, logic devices require some type of memory. The most common type of memory is random access memory. Resistive random access memory (RRAM or ReRAM) is a type of non-volatile (NV) random-access computer memory that works by changing the resistance of the memory element. RRAM can be similar to a memristor which is a hypothetical, non-linear, passive two-terminal electrical component relating electric charge and magnetic flux linkage. The memristor's electrical resistance is not constant but depends on the history of current that had previously flowed through the device. Its present resistance depends on how much electric charge flowed in what direction in the past. A RRAM cell is a device that remembers its history so when the electric power supply is turned off, the RRAM cell remembers its most recent resistance until it is turned on again. Using this property, the RRAM cell can be used as a memory cell or memory array for electronic devices.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a simplified block diagram illustrating an embodiment of a portion of an electronic device, in accordance with one embodiment of the present disclosure;

FIG. 2 is a simplified block diagram illustrating an embodiment of a portion of an electronic device, in accordance with one embodiment of the present disclosure;

FIG. 3 is a simplified block diagram illustrating an embodiment of a portion of an electronic device, in accordance with one embodiment of the present disclosure;

FIG. 4 is a simplified block diagram illustrating an embodiment of a portion of an electronic device, in accordance with one embodiment of the present disclosure;

FIG. 5 is a simplified block diagram illustrating an embodiment of a portion of an electronic device, in accordance with one embodiment of the present disclosure;

FIG. 6 is a simplified block diagram illustrating an embodiment of a portion of an electronic device, in accordance with one embodiment of the present disclosure;

FIG. 7 is a simplified block diagram illustrating an embodiment of a portion of an electronic device, in accordance with one embodiment of the present disclosure;

FIG. 8 is a simplified block diagram illustrating an embodiment of a portion of an electronic device, in accordance with one embodiment of the present disclosure;

FIG. 9 is a simplified block diagram illustrating an embodiment of a portion of an electronic device, in accordance with one embodiment of the present disclosure;

FIG. 10 is a simplified block diagram illustrating an embodiment of a portion of an electronic device, in accordance with one embodiment of the present disclosure;

FIG. 11 is a simplified block diagram illustrating an embodiment of a portion of an electronic device, in accordance with one embodiment of the present disclosure;

FIG. 12 is a simplified block diagram illustrating an embodiment of a portion of an electronic device, in accordance with one embodiment of the present disclosure;

FIG. 13 is a simplified block diagram illustrating an embodiment of a portion of an electronic device, in accordance with one embodiment of the present disclosure;

FIG. 14 is a simplified block diagram illustrating an embodiment of a portion of an electronic device, in accordance with one embodiment of the present disclosure;

FIG. 15 is a simplified block diagram illustrating an embodiment of a portion of an electronic device, in accordance with one embodiment of the present disclosure;

FIG. 16 is a simplified block diagram illustrating an embodiment of a portion of an electronic device, in accordance with one embodiment of the present disclosure;

FIG. 17 is an interposer implementing one or more of the embodiments disclosed herein; and

FIG. 18 is a computing device built in accordance with an embodiment disclosed herein.

The figures of the drawings are not necessarily drawn to scale, as their dimensions can be varied considerably without departing from the scope of the present disclosure.

### DETAILED DESCRIPTION

The following detailed description sets forth examples of substrates, assemblies, and techniques to enable a dual pedestal for memory. Features such as structure(s), function(s), and/or characteristic(s), for example, are described with reference to one embodiment as a matter of convenience; various embodiments may be implemented with any suitable one or more of the described features.

Described herein are systems and methods of a dual pedestal memory. In an example, a device may include a substrate, where the substrate includes a fill metal that provides a conductive path for an electrical connection. A first pedestal can be located over the fill metal and a second pedestal can be located over the first pedestal. The second pedestal can be a bottom electrode. In an example, the first pedestal extends at least a length of the fill metal and the second pedestal extends less than a length of the first pedestal. In addition, the device can include a memory cell over the second pedestal. The memory cell can be a device based on resistive RAM (RRAM), magnetoresistive RAM (MRAM), spin transfer torque memory (STTM), perpendicular STTM (pSTTM), in-plane STTM (iSTTM), phase change memory (PCM), oxide based RAM (OxRAM), conductive bridge RAM (CBRAM), ferroelectric RAM (FeRAM), or other types of memory. Further, the first pedestal and second pedestal can include a diffusion barrier and help to address etch compatibility issues. In some instances, the substrate includes a logic portion and a memory portion. The logic portion can include at least one micro-processor circuit and the memory portion can include non-volatile random access memory.

In the following description, various aspects of the illustrative implementations will be described using terms commonly employed by those skilled in the art to convey the substance of their work to others skilled in the art. However, it will be apparent to those skilled in the art that the embodiments disclosed herein may be practiced with only some of the described aspects. For purposes of explanation, specific numbers, materials and configurations are set forth in order to provide a thorough understanding of the illustrative implementations. However, it will be apparent to one skilled in the art that the embodiments disclosed herein may be practiced without the specific details. In other instances, well-known features are omitted or simplified in order not to obscure the illustrative implementations.

Various operations will be described as multiple discrete operations, in turn, in a manner that is most helpful in understanding the embodiments disclosed herein, however, the order of description should not be construed to imply that these operations are necessarily order dependent. In particular, these operations need not be performed in the order of presentation.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

Implementations of the embodiments disclosed herein may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. In other examples, the substrate may be a flexible substrate including 2D materials such as graphene and MoS2, organic materials such as pentacene, transparent oxides such as IGZO poly/amorphous (low temperature of dep) III-V semiconductors and Ge/Si, and other non-silicon flexible substrates. Although a few examples of materials from which the substrate may be formed are described here, any material that may serve as a foundation upon which a semiconductor device may be built falls within the spirit and scope of the embodiments disclosed herein.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments. For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous. As used herein, the terms “chip” and “die” may be used interchangeably.

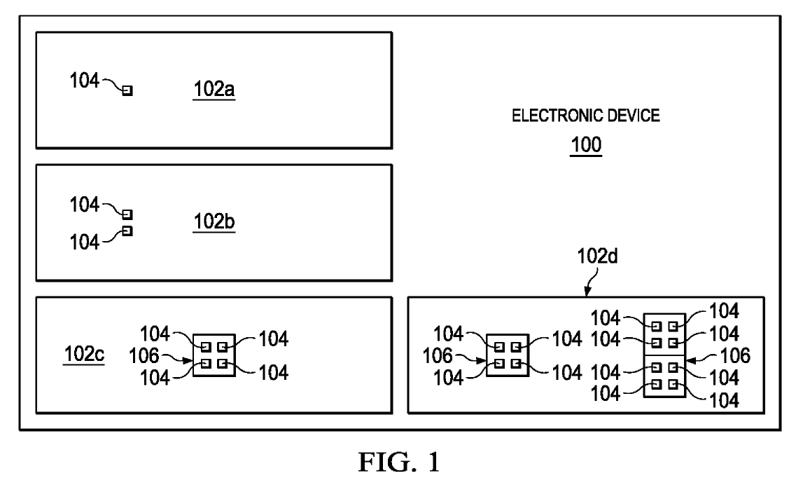

FIG. 1 is a simplified block diagram of an electronic device 100 that includes one or more instances of duel pedestal memory. Electronic device 100 can include one or more electronic elements 102a-102d. Electronic device 100 can be any electronic device that includes memory (e.g., computer, smartphone, laptop, desktop, Internet-of-Things device, vehicle, handheld electronic device, personal digital assistant, wearable, etc.) Each electronic element 102a-102d can include a memory 104 and/or one or more memory arrays 106. Each memory array 106 can be is a systematic arrangement of a plurality of memory 104, (e.g., in rows and columns) Each memory 104 can include a memory cell. Memory 104 can include a logic/memory device and memory 104 may be part of a transistor or an electronic switch that can be either in an “on” or “off” state. The term “transistor” includes a bipolar junction transistor (BJT), filed effect transistor (FET), finFET, junction gate FET (JFET), insulated gate FET (IGFET), metal-oxide-semiconductor field-effect transistors (MOSFET), n-channel field effect transistor (NFET) insulated-gate bipolar transistor, or other similar transistor that can be configured to perform the functions, features, and operations disclosed herein. In an example, the memory can be located over a first pedestal and a second pedestal. The memory may include random access memory (RAM) cells and arrays in accordance with an embodiment of the present disclosure.

Resistive RAM (RRAM or ReRAM) is a common type of non-volatile (NV) RAM that works by changing its resistance by varying a controllable feature such as, but not limited to, current, voltage, charge, etc. Typically, the RRAM is in a densely packed array and when the RRAM sits on an interconnect there are issues with connecting the RRAM to the interconnect. The memory cells of the RRAM are typically engineered with the RRAM device edge coupled or in close proximity to an electrically active component such as the transistor. Typical RRAM device stacks include metal and dielectric stacks. When the dielectric/metal material is etched, the etching needs to stop on the previous layer that typically includes the interconnect metal/dielectrics. In addition, the etch must be compatible with the interconnect system it is landing on and must not redeposit conductive material on a sidewall during a bottom electrode etch. However, stopping the etch on the interconnect metal can be difficult and the etch itself can cause edge defects, leakage, lateral oxidation, metal incompatibly, can create metal polymers, corrode the metal, and other issues that are problematic for some RRAM.

Memory 104 can be configured to resolve these issues (and others). For example, memory 104 can be configured to be decoupled from the electrically active component by introducing a pedestal between metal contacts. During the creation of at least a portion of memory 104, the etch can be ensured to end on a dielectric so an resputter material will be non-conductive. This can be done by using a pedestal. The pedestal can include a diffusion barrier to help address the etch compatibility issues. Also, a second pedestal can be configured as a bottom electrode that is smaller than the memory element to help minimize sidewall resputter.

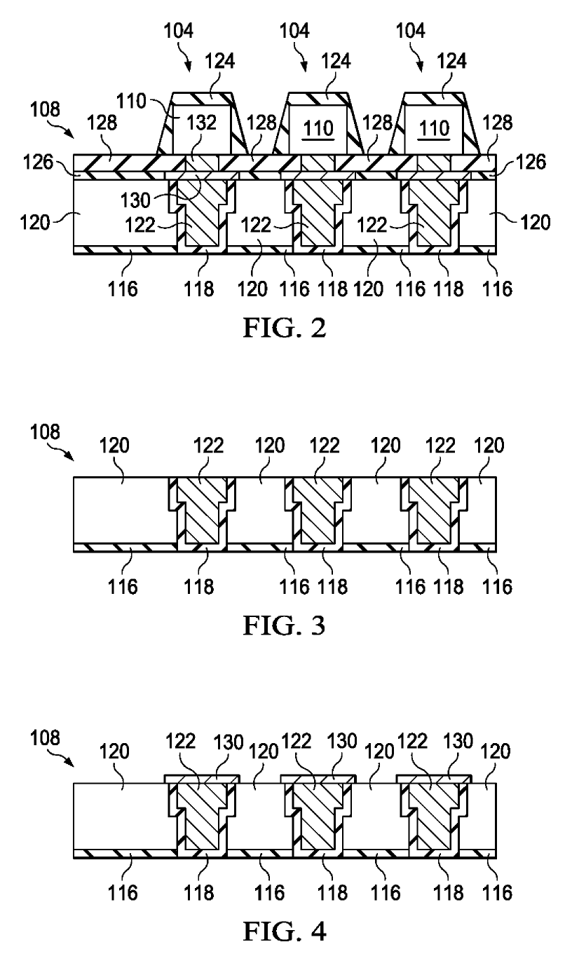

Turning to FIG. 2, FIG. 2 illustrates one embodiment of a memory 104 that includes a dual pedestal. As illustrated in FIG. 2, substrate 108 can include a bottom insulator 116, an insulating layer 118, an interlayer dielectric (ILD) 120, and fill metal 122. A first dielectric layer 126 can be on substrate 108 and a second dielectric layer 128 can be on first dielectric layer 126. A first pedestal 130 can be above fill metal 122 and in first dielectric layer 126. A second pedestal 132 can be above first pedestal 130 and in second dielectric layer 128. Memory 104 can be on or include second pedestal 132. Memory 104 can include memory cell 110 and memory cell 110 may be a device based on resistive RAM (RRAM), magnetoresistive RAM (MRAM), spin transfer torque memory (STTM), perpendicular STTM (pSTTM), in-plane STTM (iSTTM), phase change memory (PCM), oxide based RAM (OxRAM), conductive bridge RAM (CBRAM), ferroelectric RAM (FeRAM), etc. An oxide layer 124 can be over memory cell 110.

Substrate 108 can be configured to provide a base or first pedestal for memory 104 and can include silicon or some other non-metal layer. In an implementation, substrate 108 may be a non-silicon flexible substrate. Bottom insulator 116 may be a bottom electrode insulator to insulate substrate 108 from a bottom electrode (not shown). Bottom insulator 116 can be configured as an etch stop during patterning, as an interconnect diffusion barrier, an adhesion between two interconnect layers, a hermetic barrier to prevent moisture degradation, and/or as an electromigration resistance for metal interconnects. Bottom insulator 116 can be comprised of silicon nitride (SiN), silicon cyanide (SiCN), silicon cyanate (SiOCN), aluminum oxide (AlO), etc.

Insulating layer 118 can be configured as a diffusion barrier, liner, and/or adhesion promoter. Insulating layer 118 can allow for good adhesion between ILD 120 and fill metal 122, help to prevent out diffusion of fill metal 122 into ILD 120, and/or provide some electromigration resistance for fill metal 122. Insulating layer 118 can be comprised of or include tantalum (Ta), tantalum nitride (TaN), titanium (Ti), titanium nitride (TiN), ruthenium (Ru), cobalt (Co), etc.

ILD 120 can be configured as a low-k dielectric with low dissipation and low capacitance to allow low power, high speed signal communications and can be an insulating material that exhibits weak polarization when subjected to an externally applied electric field. ILD 120 can forms a matrix or provide mechanical support that allows itself to be patterned to facilitate metal interconnect wire fabrication. ILD 120 can be comprised of or include silicon monoxide (SiO), SiON, SiOCN, SiN, spin on glass, or other spin on cure-able dielectrics

Fill metal 122 can provide a conductive path for an electrical connection to an electrical component coupled to second pedestal 132. More specifically, fill metal 122 may be a metal-2 layer and can be configured to conduct electrical signals with low resistance and provide electromigration resistant. Fill metal 122 can be comprised of aluminum (Al), copper (Cu), tungsten (W), Co, Ru, nickel (Ni), iron (Fe), molybdenum (Mo), etc. Fill metal 122 can also be comprised of or include alloying materials such as an aluminum alloy, copper alloy, cobalt alloy, tungsten alloy, ruthenium alloy, manganese alloy, magnesium alloy, boron alloy, phosphorus alloy, nitrogen alloy, carbon alloy, sulfur alloy, etc.

First dielectric layer 126 can be configured as an etch stop during patterning, as an interconnect diffusion barrier, an adhesion between two interconnect layers, a hermetic barrier to prevent moisture degradation, and/or as an electromigration resistance for metal interconnects. First dielectric layer 126 can be comprised of or include SiN, SiCN, SiOCN, AlO, etc. Similarly, second dielectric layer 128 can be configured as an etch stop during patterning, as an interconnect diffusion barrier, an adhesion between two interconnect layers, a hermetic barrier to prevent moisture degradation, and/or as an electromigration resistance for metal interconnects. Second dielectric layer 128 can be comprised of or include SiN, SiCN, SiOCN, AlO, etc. First dielectric layer 126 and second dielectric layer 128 may be comprised of the same material or may be comprised of a different material.

First pedestal 130 can be can be configured as a diffusion barrier, liner, and/or adhesion promoter. First pedestal 118 can allow for good adhesion between fill metal 122 (or insulating layer 118) and second pedestal 132, help to prevent diffusion of fill metal 122 to second pedestal 132 and ILD 120, and/or provide some electromigration resistance for fill metal 122. First pedestal 130 can be comprised of or include Ta, TaN, Ti, TiN, Ru, Co, etc.

Second pedestal 132 can be configured as a bottom electrode. Second pedestal 132 can provide an interconnect to fill metal 122 and allow for appropriate bottom electrode or contact properties to allow memory cell 110 to function. The properties can include, but are not limited to, crystallographic orientation, work function, oxygen reactivity, thermal conductivity, etc. Second pedestal 132 can be comprised of or include Ta, TaN, Ti, TiN, Ru, platinum (Pt), iridium (Ir), platinum manganese (PtMn), etc. and the type of material depends on the type of memory cell 110.

Turning to FIG. 3, FIG. 3 illustrates one embodiment of one of the early stages of building a dual pedestal memory. In an embodiment, substrate 108 can be created by layering and etching the various layers. The thickness of substrate 108 can be about 0.5 nm to about 5 nms. In other embodiments, other thicknesses that enable the operations and features discussed herein may be used.

Turning to FIG. 4, FIG. 4 illustrates one embodiment of one of the early stages of building a dual pedestal memory. In an embodiment, first pedestal 130 can be placed, deposited, etc. on top of fill metal 122. First pedestal 130 can be positioned over fill metal 122 and edges of first pedestal 130 may extend to or slightly past insulating layer 118.

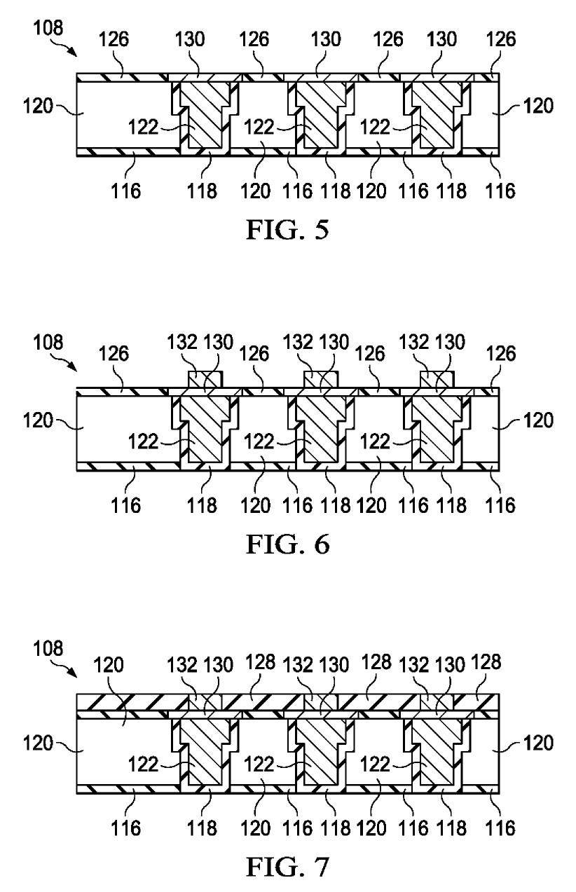

Turning to FIG. 5, FIG. 5 illustrates one embodiment of one of the stages of building a dual pedestal memory. In an embodiment, first dielectric layer 126 can be placed, deposited, etc. on top of ILD 120 and between each first pedestal 130. A top surface of first dielectric layer 126 can be about even with a top surface of first pedestal 130.

Turning to FIG. 6, FIG. 6 illustrates one embodiment of one of the early stages of building a dual pedestal memory. In an embodiment, second pedestal 132 can be placed, deposited, etc. on top of first pedestal 130. Second pedestal 132 can be about the wide of fill metal 122. In an example, edges of second pedestal 132 do not extend to the edges of first pedestal 130 and a width of second pedestal 132 is less than the width of first pedestal 130.

Turning to FIG. 7, FIG. 7 illustrates one embodiment of one of the stages of building a dual pedestal memory. In an embodiment, second dielectric layer 128 can be placed, deposited, etc. on the top of first dielectric layer 126. A top surface of second dielectric layer 128 can be about even with a top surface of second pedestal 132.

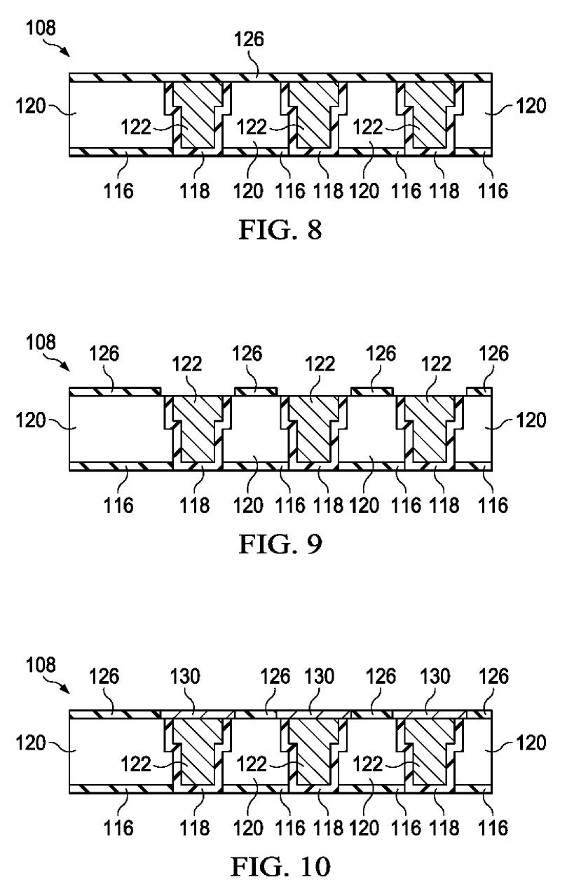

Turning to FIG. 8, FIG. 8 illustrates one embodiment of one of the stages of building a dual pedestal memory. In an embodiment, first dielectric layer 126 can be placed, deposited, etc. on substrate 108. The surface can be polished and cleaned.

Turning to FIG. 9, FIG. 9 illustrates one embodiment of one of the stages of building a dual pedestal RAM. In an embodiment, first dielectric layer 126 can be etched to create an opening that will accommodate first pedestal 130. The opening can be over fill metal 122 and the size of the opening can extend to or slightly past insulating layer 118.

Turning to FIG. 10, FIG. 10 illustrates one embodiment of one of the stages of building a dual pedestal memory. In an embodiment, first pedestal 130 can be placed, deposited, etc. on top of fill metal 122. First pedestal 130 can be positioned over fill metal 122 and edges of first pedestal 130 may extend to or slightly past insulating layer 118. This allows first pedestal 130 to function as a diffusion barrier and help prevent metal on metal from escaping or diffusing out.

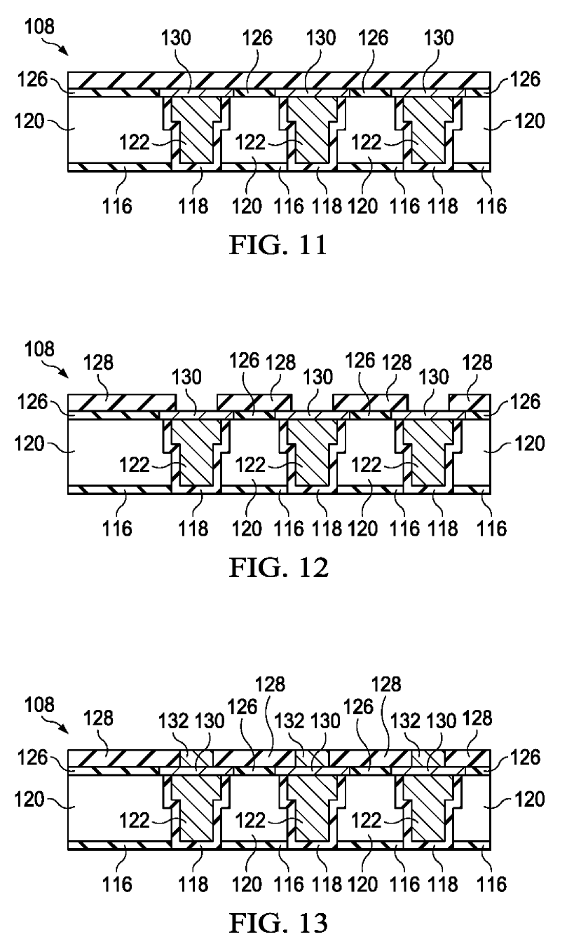

Turning to FIG. 11, FIG. 11 illustrates one embodiment of one of the stages of building a dual pedestal memory. In an embodiment, second dielectric layer 128 can be placed, deposited, etc. on first dielectric layer 126. Second dielectric layer 128 can be polished and cleaned.

Turning to FIG. 12, FIG. 12 illustrates one embodiment of one of the stages of building a dual pedestal memory. In an embodiment, second dielectric layer 128 can be etched to create an opening that will accommodate second pedestal 132. The size of the opening can be about the wide of fill metal 122.

Turning to FIG. 13, FIG. 13 illustrates one embodiment of one of the stages of building a dual pedestal memory. In an embodiment, second pedestal 132 can be placed, deposited, etc. on top of first pedestal 130. Second pedestal 132 can be about the wide of fill metal 122. In an example, edges of second pedestal 132 do not extend to the edges of first pedestal 130 and a width of second pedestal 132 is less than the width of first pedestal 130.

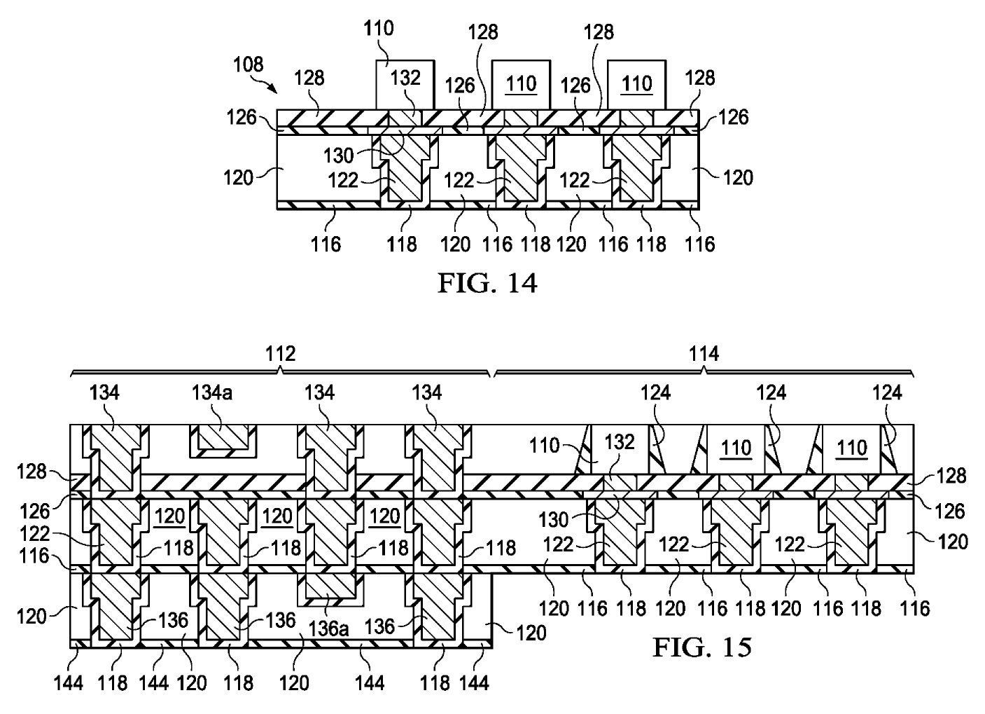

Turning to FIG. 14, FIG. 14 illustrates one embodiment of one of the stages of dual pedestal memory. In an embodiment, memory cell 110 can be placed, deposited, etc. on second pedestal 132. When etching during the creation of memory cell 110, the etch lands on second dielectric layer 128 and not on second pedestal 132. Because there is no such thing as a perfect etch and the etch will almost always interact with other metals, it is much easier to get exclusivity between dielectrics and metal (e.g., second dielectric layer 128) then metal and metal (e.g., second pedestal 132). By making second pedestal 132 smaller than first pedestal 130 and memory cell 110, edge compatibility issues and diffusion issues associated with metal to metal contact can be at least partially resolved. By making second pedestal 132 smaller and including first pedestal 130, when etching for memory cell 110, the etch damaging effects to second pedestal 132 can be reduced because the etching is isolated and landing on second dielectric layer 128.

Turning to FIG. 15, FIG. 15 illustrates one embodiment of one of dual pedestal memory. In an embodiment, substrate 108 can include a logic portion 112 and a memory portion 114. In an example, memory portion 114 can include memory cell 110. In this example, memory cell 110 can include embedded non-volatile RAM (NV-RAM). Logic portion 112 can include fill metal 134 and logic circuitry 136. Fill metal 134 can be configured as an interconnect wire and can include the same metal as fill metal 122 or a different type of metal. Fill metal 134 can be used to electrically couple or connect a layer above 134 with a layer below 134. Fill metal 134a does not connect to a bottom layer.

Logic circuitry 136 can include transistors, logic (e.g., adders, registers, etc), micro-processor circuits for processing data, and other circuitry. Logic circuitry 136 can communicate with memory cell 110 and cause data to be stored in one or more memory cells 110. Logic circuitry 136 and memory cell 110 can be located on the same substrate or wafer.

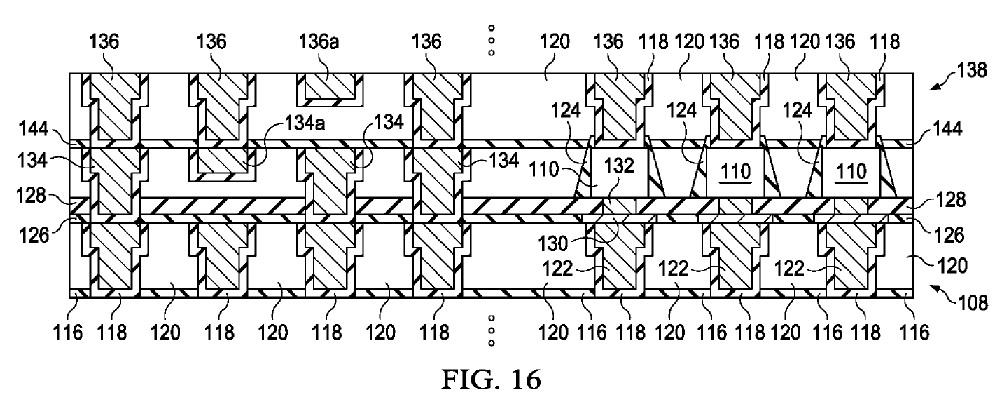

Turning to FIG. 16, FIG. 16 illustrates one embodiment of one of dual pedestal memory. In an embodiment, one or more different layers may be stacked above or below substrate 108. For example, a second tier 138 can include various electronics and interconnects. More specifically, via 144 can couple fill metal 136 to fill metal 134. This can help facilitate scaling of logic devices.

Scaling of logic devices is typically accomplished by reducing the size of the logic device. One approach is based on increasing the number of logic elements per unit area. To increase the number of logic elements per unit area, the density of dies needs to be increased and additional logic devices need to be fabricated above the silicon. To increase the density of dies in an integrated circuit (IC) package of a particular footprint, dies may be stacked on top of each other such that instead of fabricating logic devices in a silicon single crystal layer on top of a silicon wafer, additional logic devices can be fabricated above the silicon.

In the above examples, the semiconductor substrate for substrate 108 (and any additional layers) may be formed using alternate materials, which may or may not be combined with silicon. This includes, but is not limited to, germanium, indium antimonide, lead telluride, indium arsenide, indium phosphide, gallium arsenide, indium gallium arsenide, gallium antimonide, or other combinations of group III-V or group IV materials. In other examples, the substrate of any layer may be a flexible substrate including 2D materials such as graphene and MoS2, organic materials such as pentacene, transparent oxides such as IGZO poly/amorphous (low temperature of dep) III-V semiconductors and Ge/Si, and other non-silicon flexible substrates.

In an example, a plurality of transistors, such as metal-oxide-semiconductor field-effect transistors (MOSFET or simply MOS transistors), that include memory 104, may be fabricated on the substrate. In various embodiments, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that various embodiments may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, when viewed as a cross-section of the transistor along the source-channel-drain direction, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

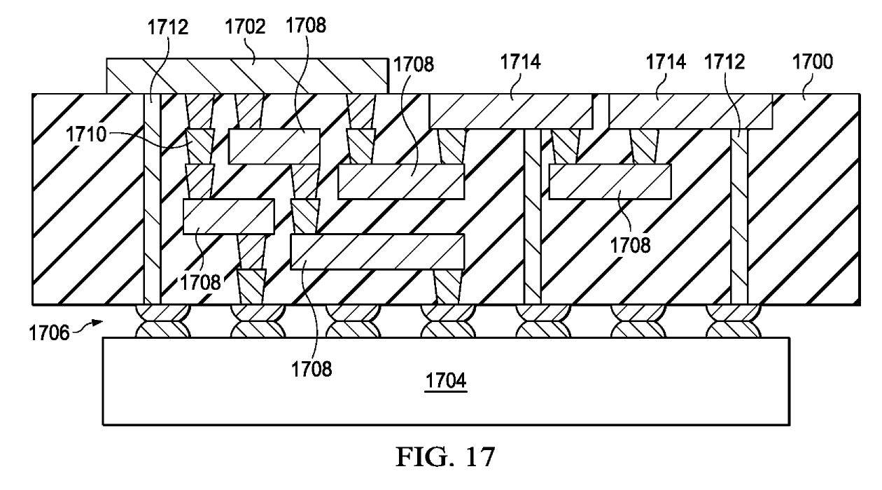

Turning to FIG. 17, FIG. 17 illustrates an interposer 1700 that can include or interact with one or more embodiments disclosed herein. The interposer 1700 is an intervening substrate used to bridge a first substrate 1702 to a second substrate 1704. The first substrate 1702 may be, for instance, an integrated circuit die. The second substrate 1704 may be, for instance, a memory module, a computer motherboard, or another integrated circuit die. Generally, the purpose of an interposer 1700 is to spread a connection to a wider pitch or to reroute a connection to a different connection. For example, an interposer 1700 may couple an integrated circuit die to a ball grid array (BGA) 1706 that can subsequently be coupled to the second substrate 1704. In some embodiments, the first and second substrates 1702/1704 are attached to opposing sides of the interposer 1700. In other embodiments, the first and second substrates 1702/1704 are attached to the same side of the interposer 1700. And in further embodiments, three or more substrates are interconnected by way of the interposer 1700.

The interposer 1700 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 1708 and vias 1710, including but not limited to through-silicon vias (TSVs) 1712. The interposer 1700 may further include embedded devices 1714, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 1700. In accordance with various embodiments, apparatuses or processes disclosed herein may be used in the fabrication of interposer 1700.

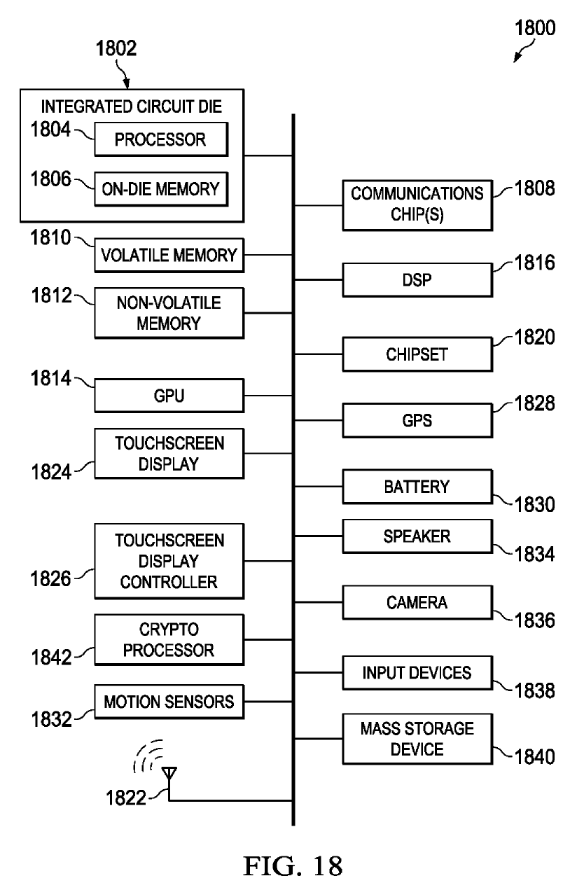

Turning to FIG. 18, FIG. 18 illustrates a computing device 1800 in accordance with various embodiments. The computing device 1800 may include a number of components. In one embodiment, these components are attached to one or more motherboards. In an alternate embodiment, some or all of these components are fabricated onto a single system-on-a-chip (SoC) die. The components in the computing device 1800 include, but are not limited to, an integrated circuit die 1802 and at least one communications logic unit 1808. In some implementations the communications logic unit 1808 is fabricated within the integrated circuit die 1802 while in other implementations the communications logic unit 1808 is fabricated in a separate integrated circuit chip that may be bonded to a substrate or motherboard that is shared with or electronically coupled to the integrated circuit die 1802. The integrated circuit die 1802 may include a CPU 1804 as well as on-die memory 1806, often used as cache memory, that can be provided by technologies such as embedded DRAM (eDRAM) or spin-transfer torque memory (STTM or STT-MRAM).

Computing device 1800 may include other components that may or may not be physically and electrically coupled to the motherboard or fabricated within an SoC die. These other components include, but are not limited to, volatile memory 1810 (e.g., DRAM), non-volatile memory 1812 (e.g., ROM or flash memory), a graphics processing unit 1814 (GPU), a digital signal processor 1816, a crypto processor 1842 (a specialized processor that executes cryptographic algorithms within hardware), a chipset 1820, an antenna 1822, a display or a touchscreen display 1824, a touchscreen controller 1826, a battery 1828 or other power source, a power amplifier (not shown), a voltage regulator (not shown), a global positioning system (GPS) device 1828, a compass 1830, a motion coprocessor or sensors 1832 (that may include an accelerometer, a gyroscope, and a compass), a speaker 1834, a camera 1836, user input devices 1838 (such as a keyboard, mouse, stylus, and touchpad), and a mass storage device 1840 (such as hard disk drive, compact disk (CD), digital versatile disk (DVD), and so forth).

The communications logic unit 1808 enables wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communications logic unit 1808 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1800 may include a plurality of communications logic units 1808. For instance, a first communications logic unit 1808 may be dedicated to shorter range wireless communications such as Wi-Fi and Bluetooth and a second communications logic unit 1808 may be dedicated to longer range wireless communications such as GPS, EDGE, GPRS, CDMA, WiMAX, LTE, Ev-DO, and others.

The processor 1804 of the computing device 1800 can communicate with one or more devices that are formed in accordance with various embodiments. The term “processor” may refer to any device or portion of a device that processes electronic data from registers and/or memory to transform that electronic data into other electronic data that may be stored in registers and/or memory.

The communications logic unit 1808 may also include one or more devices, such as transistors or metal interconnects, that are in communication with various ones of the embodiments disclosed herein. In further embodiments, another component housed within the computing device 1200 may contain one or more devices, such as transistors or metal interconnects, that are formed in accordance with implementations of the embodiments disclosed herein.

In various embodiments, the computing device 1800 may be a laptop computer, a netbook computer, a notebook computer, an ultrabook computer, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1800 may be any other electronic device that processes data.

The above description of illustrated implementations, including what is described in the Abstract, is not intended to be exhaustive or to limit the scope of the disclosure to the precise forms disclosed. While specific implementations of, and examples for, the embodiments disclosed herein are described herein for illustrative purposes, various equivalent modifications are possible within the scope of the disclosure, as those skilled in the relevant art will recognize.

### Other Notes and Examples

Example 1 is an apparatus including a substrate, wherein the substrate includes a fill metal, a first pedestal on the substrate, wherein the first pedestal is over the fill metal, and a second pedestal over the first pedestal, where the second pedestal is a bottom electrode.

In Example 2, the subject matter of Example 1 can optionally include where the first pedestal extends at least a length of the fill metal.

In Example 3, the subject matter of any one of Examples 1-2 can optionally include where the second pedestal extends less than a length of the first pedestal.

In Example 4, the subject matter of any one of Examples 1-3 can optionally include a memory cell over of the second pedestal.

In Example 5, the subject matter of any one of Examples 1-4 can optionally include where the memory cell is a device based on resistive RAM (RRAM), magnetoresistive RAM (MRAM), spin transfer torque memory (STTM), perpendicular STTM (pSTTM), in-plane STTM (iSTTM), phase change memory (PCM), oxide based RAM (OxRAM), conductive bridge RAM (CBRAM), or ferroelectric RAM (FeRAM).

In Example 6, the subject matter of any one of Examples 1-5 can optionally include where the first pedestal includes a diffusion barrier. In an example, the diffusion barrier helps to address etch compatibility issues.

In Example 7, the subject matter of any one of Examples 1-6 can optionally include where the substrate includes a logic portion and a memory portion.

In Example 8, the subject matter of any one of Examples 1-7 can optionally include where the logic portion includes at least one micro-processor circuit.

In Example 9, the subject matter of any one of Examples 1-8 can optionally include where the memory portion includes non-volatile random access memory.

In Example 10, a method can include adding a first pedestal on a substrate, where the substrate includes a fill metal and the first pedestal is over the fill metal and adding a second pedestal over the first pedestal, where the second pedestal is a bottom electrode.

In Example 11, the subject matter of Example 10 can optionally include where the first pedestal extends at least a length of the fill metal.

In Example 12, the subject matter of any one of Examples 10-11 can optionally include where the second pedestal extends less than a length of the first pedestal.

In Example 13, the subject matter of any one of Examples 10-12 can optionally include adding a memory cell over the second pedestal.

In Example 14, the subject matter of any one of Examples 10-13 can optionally include where the substrate includes a logic portion and a memory portion.

In Example 15, the subject matter of any one of Examples 10-14 can optionally include where the logic portion includes at least one micro-processor circuit.

In Example 16, the subject matter of any one of Examples 10-15 can optionally include where the memory portion includes non-volatile random access memory.

Example 17 is a computing device including a processor mounted on a substrate, where the substrate includes a fill metal a communications logic unit within the processor, a memory within the processor, a graphics processing unit within the computing device, an antenna within the computing device, a display on the computing device, a battery within the computing device, a power amplifier within the processor, and a voltage regulator within the processor. The processor can include a first pedestal on the substrate, where the first pedestal is over the fill metal, and a second pedestal over the first pedestal, where the second pedestal is a bottom electrode.

Example 18 the subject matter of Example 17 can optionally include where the first pedestal extends at least a length of the fill metal.

In Example 19, the subject matter of Example 17-18 can optionally include where the second pedestal extends less than a length of the first pedestal.

In Example 20, the subject matter of any one of the Examples 17-19 can optionally include where the processor further includes a memory cell over top of the second pedestal.

In Example 21, the subject matter of any one of the Examples 17-20 can optionally include where the memory cell is a device based on resistive RAM (RRAM), magnetoresistive RAM (MRAM), spin transfer torque memory (STTM), perpendicular STTM (pSTTM), in-plane STTM (iSTTM), phase change memory (PCM), oxide based RAM (OxRAM), conductive bridge RAM (CBRAM), or ferroelectric RAM (FeRAM).

Example 22 is an integrated circuit (IC) assembly including a substrate, where the substrate includes a fill metal, a first pedestal on the substrate, where the first pedestal is over the fill metal, and a second pedestal over the first pedestal, where the second pedestal is a bottom electrode.

In Example 23, the subject matter of Example 22 can optionally include where the first pedestal extends at least a length of the fill metal.

In Example 24, the subject matter of any one of the Examples 22-23 can optionally include where the second pedestal extends less than a length of the first pedestal.

In Example 25, the subject matter of any one of the Examples 22-24 can optionally include a memory cell over top of the second pedestal.

In Example 26, the subject matter of any one of Examples 1-9 can optionally include where the fill metal includes aluminum (Al), copper (Cu), tungsten (W), Co, Ru, nickel (Ni), iron (Fe), or molybdenum (Mo).

In Example 27, the subject matter of any one of Examples 1-10 can optionally include where the first pedestal includes tantalum (Ta), tantalum nitride (TaN), titanium (Ti), titanium nitride (TiN), ruthenium (Ru), cobalt (Co).

In Example 28, the subject matter of any one of Examples 1-11 can optionally include where the second pedestal includes tantalum (Ta), tantalum nitride (TaN), titanium (Ti), titanium nitride (TiN), ruthenium (Ru), platinum (Pt), iridium (Ir), or platinum manganese (PtMn).

In Example 29, the subject matter of any one of Examples 10-16 can optionally include where the fill metal includes aluminum (Al), copper (Cu), tungsten (W), Co, Ru, nickel (Ni), iron (Fe), or molybdenum (Mo).

In Example 30, the subject matter of any one of Examples 10-17 can optionally include where the first pedestal includes tantalum (Ta), tantalum nitride (TaN), titanium (Ti), titanium nitride (TiN), ruthenium (Ru), cobalt (Co).

In Example 31, the subject matter of any one of Examples 10-18 can optionally include where the second pedestal includes tantalum (Ta), tantalum nitride (TaN), titanium (Ti), titanium nitride (TiN), ruthenium (Ru), platinum (Pt), iridium (Ir), or platinum manganese (PtMn).

In Example 32, the subject matter of any one of the Examples 17-20 can optionally include where the fill metal includes aluminum (Al), copper (Cu), tungsten (W), Co, Ru, nickel (Ni), iron (Fe), or molybdenum (Mo).

In Example 33, the subject matter of any one of Examples 17-21 can optionally include where the first pedestal includes tantalum (Ta), tantalum nitride (TaN), titanium (Ti), titanium nitride (TiN), ruthenium (Ru), cobalt (Co).

In Example 34, the subject matter of any one of Examples 17-22 can optionally include where the second pedestal includes tantalum (Ta), tantalum nitride (TaN), titanium (Ti), titanium nitride (TiN), ruthenium (Ru), platinum (Pt), iridium (Ir), or platinum manganese (PtMn).

In Example 35, the subject matter of any one of the Examples 22-25 can optionally include where the fill metal includes aluminum (Al), copper (Cu), tungsten (W), Co, Ru, nickel (Ni), iron (Fe), or molybdenum (Mo).

In Example 36, the subject matter of any one of Examples 22-25 can optionally include where the first pedestal includes tantalum (Ta), tantalum nitride (TaN), titanium (Ti), titanium nitride (TiN), ruthenium (Ru), cobalt (Co).

In Example 37, the subject matter of any one of Examples 22-26 can optionally include where the second pedestal includes tantalum (Ta), tantalum nitride (TaN), titanium (Ti), titanium nitride (TiN), ruthenium (Ru), platinum (Pt), iridium (Ir), or platinum manganese (PtMn).

1-25. (canceled)

26. An apparatus, comprising:
a substrate, wherein the substrate includes a metal;
a first pedestal over the substrate, wherein the first pedestal is over the metal; and
a second pedestal over the first pedestal, wherein the second pedestal is a bottom electrode for a memory cell.

27. The apparatus of claim 26, wherein the first pedestal extends at least a length of the metal.

28. The apparatus of claim 26, wherein the second pedestal extends less than a length of the first pedestal.

29. The apparatus of claim 26, further comprising:
a memory cell over the second pedestal.

30. The apparatus of claim 29, wherein the memory cell is a resistive RAM (RRAM) device, a magnetoresistive RAM (MRAM) device, a spin transfer torque memory (STTM) device, a perpendicular STTM (pSTTM) device, an in-plane STTM (iSTTM) device, a phase change memory (PCM) device, an oxide-based RAM (OxRAM) device, a conductive bridge RAM (CBRAM) device, or a ferroelectric RAM (FeRAM) device.

31. The apparatus of claim 26, wherein the metal is a fill metal.

32. The apparatus of claim 26, wherein the substrate includes a logic portion and a memory portion.

33. The apparatus of claim 32, wherein the logic portion includes at least one micro-processor circuit and the memory portion includes non-volatile random access memory.

34. The apparatus of claim 26, wherein the metal includes aluminum (Al), copper (Cu), tungsten (W), Co, Ru, nickel (Ni), iron (Fe), or molybdenum (Mo).

35. The apparatus of claim 26, wherein the first pedestal includes tantalum (Ta), tantalum nitride (TaN), titanium (Ti), titanium nitride (TiN), ruthenium (Ru), cobalt (Co).

36. The apparatus of claim 26, wherein the second pedestal includes tantalum (Ta), tantalum nitride (TaN), titanium (Ti), titanium nitride (TiN), ruthenium (Ru), platinum (Pt), iridium (Ir), or platinum manganese (PtMn).

37. A method, comprising:
forming a first pedestal on a substrate, wherein the substrate includes a fill metal and the first pedestal is over the fill metal; and
forming a second pedestal over the first pedestal, wherein the second pedestal is a bottom electrode for a memory cell.

38. The method of claim 37, wherein the first pedestal extends at least a length of the fill metal and the second pedestal extends less than a length of the first pedestal.

39. The method of claim 37, further comprising:
forming a memory cell over the second pedestal.

40. The method of claim 37, wherein the substrate includes a logic portion and a memory portion.

41. A computing device, comprising:
a processing device, including:
a first pedestal over a fill metal, and
a second pedestal over the first pedestal, wherein the second pedestal is a bottom electrode of a memory cell.

42. The computing device of claim 41, wherein the first pedestal extends at least a length of the fill metal.

43. The computing device of claim 41, wherein the second pedestal extends less than a length of the first pedestal.

44. The computing device of claim 41, wherein the memory cell is a resistive RAM (RRAM) device, a magnetoresistive RAM (MRAM) device, a spin transfer torque memory (STTM) device, a perpendicular STTM (pSTTM) device, an in-plane STTM (iSTTM) device, a phase change memory (PCM) device, an oxide-based RAM (OxRAM) device, a conductive bridge RAM (CBRAM) device, or a ferroelectric RAM (FeRAM) device.

45. The computing device of claim 41, wherein the computing device further includes a display coupled to the processing device.
